(19) United States
(12) Patent Application Publication
(10) Pub. No.: US 2016/0343598 A1
(43) Pub. Date: Nov. 24, 2016

(54) SEMICONDUCTOR DEVICE MANUFACTURING METHOD AND FOUP TO BE USED THEREFOR

(71) Applicant: Renesas Electronics Corporation, Tokyo (JP)

(72) Inventors: Jiro SAKAGUCHI, Ibaraki (JP); Akira KOIWA, Ibaraki (JP); Kaichiro KOBAYASHI, Ibaraki (JP); Kenichi SATO, Ibaraki (JP); Naohide HAMADA, Ibaraki (JP); Nobuaki TOMA, Ibaraki (JP)

(21) Appl. No.: 15/082,123

(22) Filed: Mar. 28, 2016

(30) Foreign Application Priority Data
May 21, 2015 (JP) 2015-103580

(51) Int. Cl. H01L 21/673; H01L 21/677

(52) U.S. Cl. CPC H01L 21/67389; H01L 21/67356; H01L 21/67769

(57) ABSTRACT

A semiconductor device manufacturing method which uses a FOUP capable of suppressing semiconductor substrate defects due to outgas. The FOUP includes: a main body having an opening for taking in or out a semiconductor wafer; a cover detachably attached to the main body in close contact with the main body in a manner to cover the opening; an intake hole and an exhaust hole which are formed in the main body; and a first filter provided on the intake hole and a second filter provided on the exhaust hole. With the semiconductor wafer housed in the internal space of the main body, the FOUP is ventilated by taking external air into the internal space from the intake hole through the first filter and taking the air in the internal space out of the main body from the exhaust hole.

### CROSS-REFERENCE TO RELATED APPLICATIONS

The disclosure of Japanese Patent Application No. 2015-103580 filed on May 21, 2015 including the specification, drawings and abstract is incorporated herein by reference in its entirety.

### BACKGROUND

The present invention relates to a FOUP (Front Opening Unified Pod) and a semiconductor device manufacturing technique which uses the FOUP.

The FOUP is known as a container for carrying and storing a wafer which is used in the manufacturing line for a semiconductor wafer (semiconductor substrate, hereinafter simply called a wafer).

For the FOUP, external airtightness is important in order to prevent foreign substances from the outside from infiltrating the wafer housed in it, so the FOUP is a hermetic wafer container. Since it is a hermetic container, outgas generated from the wafer in the FOUP stagnates in the FOUP.

Therefore, the inside of the FOUP must be cleaned periodically.

Japanese Unexamined Patent Application Publication No. 2014-60375 discloses the shape of the FOUP whose inside can be cleaned efficiently.

### SUMMARY

However, in the wafer manufacturing line, there are cases that after completion of a prescribed process, the wafer is temporarily stored in the FOUP and then the next step is started while the wafer remains housed in the FOUP. In such a case, the following problem may arise: outgas generated from the wafer stagnates in the FOUP and the outgas reattaches to the wafer without being taken out of the FOUP, resulting in a product defect. An object of the present invention is to increase the productivity of a semiconductor device. Another object thereof is to enhance the reliability of the semiconductor device.

The above and further objects and novel features of the invention will more fully appear from the following detailed description in this specification and the accompanying drawings.

According to one aspect of the present invention, there is provided a semiconductor device manufacturing method which includes the steps of: (a) forming a gate insulating film over a front surface of a semiconductor substrate; (b) forming a gate electrode over the gate insulating film; (c) forming a sidewall spacer comprised of a first insulating film over the front surface of the semiconductor substrate and on a sidewall of the gate electrode; and (d) forming a source region and a drain region on a front surface side of the semiconductor substrate. Furthermore, it includes the steps of: (e) after the steps (a) to (d), forming an etching stopper film comprised of a second insulating film over the gate electrode, over the sidewall spacer, over the source region, and over the drain region; and (f) after the step (e), storing the semiconductor substrate in a FOUP temporarily. Furthermore, the first insulating film and the second insulating film contain silicon and nitrogen, and at the step (f), at least one of the first insulating film and the second insulating film is formed over a back surface of the semiconductor substrate. The FOUP includes a main body having an opening for taking in or out the semiconductor substrate and including an internal space, a cover detachably attached to the main body in close contact with the main body in a manner to cover the opening, a first hole and a second hole which are formed in the main body, and a filter provided on each of the first hole and the second hole. At the step (f), with the semiconductor substrate housed in the internal space of the FOUP, external air is taken into the internal space from one of the first hole and the second hole through the filter and air in the internal space is taken out of the main body from the other of the first hole and the second hole, and at the step (f), the FOUP is stored in a cleanroom.

According to a second aspect of the present invention, there is provided a semiconductor device manufacturing method which includes the steps of: (a) forming a gate insulating film over a front surface of a semiconductor substrate; (b) forming a gate electrode over the gate insulating film; (c) forming a sidewall spacer comprised of a first insulating film over the front surface of the semiconductor substrate and on a sidewall of the gate electrode; and (d) forming a source region and a drain region on a front surface side of the semiconductor substrate. Furthermore, it includes the steps of: (e) after the steps (a) to (d), forming an etching stopper film comprised of a second insulating film over the gate electrode, over the sidewall spacer, over the source region, and over the drain region; (f) forming a first interlayer insulating film over the etching stopper film; and (g) forming a first wiring in a manner to be buried in the first interlayer insulating film. Furthermore, it includes the steps of: (h) forming a barrier insulating film over the first interlayer insulating film and over the first wiring; (i) forming a second interlayer insulating film over the barrier insulating film; (j) forming a contact hole in the second interlayer insulating film; (k) forming an organic film in the contact hole; and (l) after the step (k), storing the semiconductor substrate in a FOUP temporarily. It further includes the steps of: (m) after the step (l), forming a resist pattern over the second interlayer insulating film; (n) forming a trench to be coupled with the contact hole in the second interlayer insulating film using the resist pattern as a mask; and (o) after the step (n), removing the resist pattern and the organic film. Furthermore, it includes the steps of (p) after the step (o), exposing the surface of the first wiring by removing the barrier insulating film on the bottom of the contact hole; and (q) after the step (p), forming a conductive film to fill the trench and the contact hole. The first insulating film and the second insulating film contain silicon and nitrogen, and at the step (l), at least one of the first insulating film and the second insulating film is formed over the back surface of the semiconductor substrate. The FOUP includes a main body having an opening for taking in or out the semiconductor substrate and including an internal space, a cover detachably attached to the main body in close contact with the main body in a manner to cover the opening, a first hole and a second hole which are formed in the main body, and a filter provided on each of the first hole and the second hole. At the step (l), with the semiconductor substrate housed in the internal space of the FOUP, external air is taken into the internal space from one of the first hole and the second hole through the filter and air in the internal space is taken out of the main body from the other of the first hole and the second hole, and at the step (l), the FOUP is stored in a cleanroom.

According to a third aspect of the present invention, there is provided a FOUP which includes: a main body having an opening for taking in or out a semiconductor substrate and including an internal space; a cover detachably attached to the main body in close contact with the main body in a manner to cover the opening; a first hole and a second hole which are formed in the main body; and a filter provided on each of the first hole and the second hole. With the semiconductor substrate housed in the internal space of the main body, external air can be taken into the internal space from one of the first hole and the second hole through the filter and air in the internal space can be taken out of the main body from the other of the first hole and the second hole.

According to the present invention, the productivity of a semiconductor device can be increased and the reliability of the semiconductor device can be enhanced.

### BRIEF DESCRIPTION OF THE DRAWINGS

FIG. 1 is a perspective view showing an example of the structure of the FOUP according to a first embodiment;

FIG. 2 is a sectional view showing an example of ventilation of the FOUP shown in FIG. 1;

FIG. 3 is a conceptual diagram showing an example of ventilation in the purge station of the FOUP according to the first embodiment;

FIG. 4 is a perspective view showing the structure of the FOUP as a variation of the first embodiment;

FIG. 5 is a perspective view showing an example of the structure of the FOUP according to a second embodiment;

FIG. 6 is a sectional view showing the preconditions used for simulation in the FOUP according to the second embodiment;

FIG. 7 is a data graph showing the result of simulation with the FOUP according to the second embodiment;

FIG. 8 is a perspective view showing an example of the structure of the FOUP according to a third embodiment;

FIG. 9 is a sectional view showing an example of the structure of the FOUP according to a fourth embodiment;

FIG. 10 is a fragmentary sectional view showing an example of the essential part of the semiconductor substrate manufactured by the semiconductor device manufacturing method according to a fifth embodiment;

FIG. 11 is a fragmentary sectional view showing an example of the essential part of the semiconductor substrate manufactured by the semiconductor device manufacturing method according to the fifth embodiment;

FIG. 12 is a fragmentary sectional view showing an example of the essential part of the semiconductor substrate manufactured by the semiconductor device manufacturing method according to the fifth embodiment;

FIG. 13 is a fragmentary sectional view showing an example of the essential part of the semiconductor substrate manufactured by the semiconductor device manufacturing method according to the fifth embodiment;

FIG. 14 is a fragmentary sectional view showing an example of the essential part of the semiconductor substrate manufactured by the semiconductor device manufacturing method according to the fifth embodiment;

FIG. 15 is a fragmentary sectional view showing an example of the essential part of the semiconductor substrate manufactured by the semiconductor device manufacturing method according to the fifth embodiment;

FIG. 16 is a fragmentary sectional view showing an example of the essential part of the semiconductor substrate manufactured by the semiconductor device manufacturing method according to the fifth embodiment;

FIG. 17 is a fragmentary sectional view showing an example of the essential part of the semiconductor substrate manufactured by the semiconductor device manufacturing method according to the fifth embodiment;

FIG. 18 is a fragmentary sectional view showing an example of the essential part of the semiconductor substrate manufactured by the semiconductor device manufacturing method according to the fifth embodiment;

FIG. 19 is a fragmentary sectional view showing an example of the essential part of the semiconductor substrate manufactured by the semiconductor device manufacturing method according to the fifth embodiment;

FIG. 20 is a fragmentary sectional view showing an example of the essential part of the semiconductor substrate manufactured by the semiconductor device manufacturing method according to the fifth embodiment;

FIG. 21 is a fragmentary sectional view of the structure of the essential part of the semiconductor substrate, showing how a problem occurs in the embodiments;

FIG. 22 is a fragmentary sectional view of the structure of the essential part of the semiconductor substrate, showing how a problem occurs in the embodiments; and

FIG. 23 is a fragmentary sectional view of the structure of the essential part of the semiconductor substrate, showing how a problem occurs in the embodiments.

### DETAILED DESCRIPTION

As for the preferred embodiments of the invention as described below, basically the same or similar elements or matters will not be repeatedly described except when necessary.

The preferred embodiments of the present invention may be described in different sections or separately as necessary or for the sake of convenience, but the embodiments described as such are not irrelevant to each other unless otherwise expressly stated. One embodiment may be, in whole or in part, a modified, detailed or supplementary form of another.

In the preferred embodiments as described below, when numerical information for an element (the number of pieces, numerical value, quantity, range, etc.) is indicated by a specific number, it is not limited to the specific number unless otherwise specified or theoretically limited to the specific number; it may be larger or smaller than the specific number.

In the preferred embodiments as described below, constituent elements (including constituent steps) are not necessarily essential unless otherwise specified or theoretically essential.

In the preferred embodiments as described below, as for constituent elements, it is obvious that the expression “comprising A”, “comprised of A”, “having A”, or “including A” does not exclude another element unless exclusion of another element is expressly stated. Similarly, in the preferred embodiments as described below, when a specific form or positional relation is indicated for an element, it should be interpreted to include a form or positional relation which is virtually equivalent or similar to the specific form or positional relation unless otherwise specified or theoretically limited to the specific form or positional relation. The same is true for the above numerical values and ranges.

Next, the preferred embodiments of the invention will be described in detail referring to the accompanying drawings. In all the drawings that illustrate the preferred embodiments, members with like functions are designated by like reference numerals and repeated descriptions thereof are omitted. For easy understanding, hatching may be used even in a plan view.

### First Embodiment

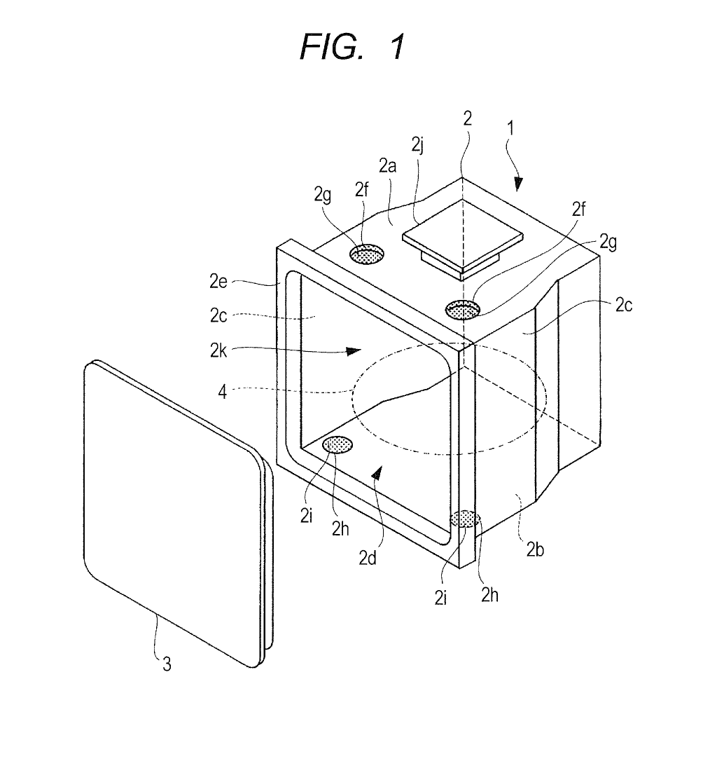

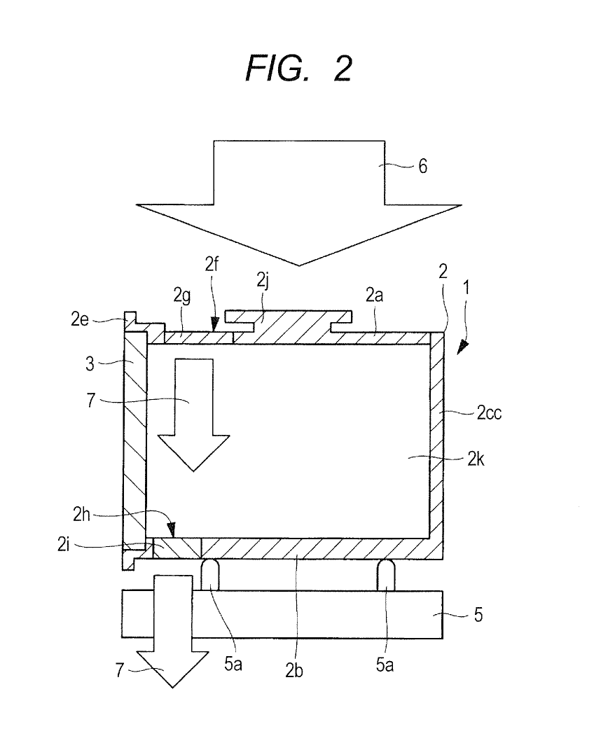

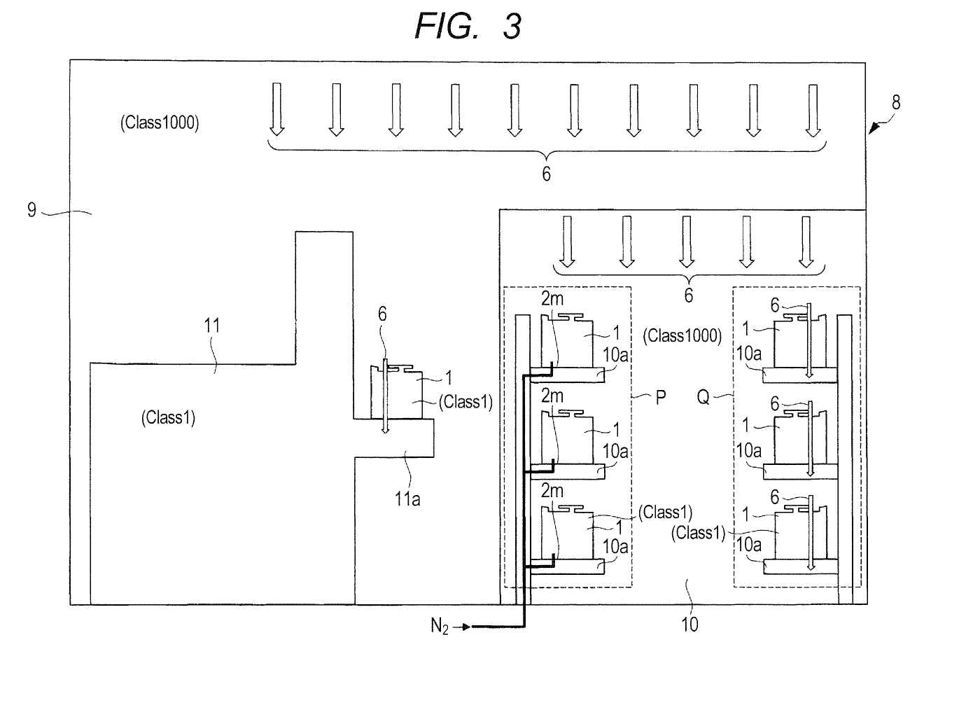

FIG. 1 is a perspective view showing an example of the structure of the FOUP according to the first embodiment; FIG. 2 is a sectional view showing an example of ventilation of the FOUP shown in FIG. 1; and FIG. 3 is a conceptual diagram showing an example of ventilation in the purge station of the FOUP according to the first embodiment.

### <FOUP>

The FOUP 1 according to the first embodiment as shown in FIG. 1, which conveys or temporarily stores the semiconductor substrate between steps of a semiconductor device manufacturing process, is a hermetic wafer container which houses a plurality of semiconductor substrates stacked and spaced apart.

The FOUP 1 according to the first embodiment is structured as follows. As shown in FIG. 1, the FOUP includes a main body 2 having an opening 2d for taking in or out a semiconductor wafer 4 as a semiconductor substrate and including an internal space 2k, and a cover 3 which is detachably attached to the main body 2 in close contact with the main body 2 in a manner to cover the opening 2d.

The main body 2 includes a ceiling surface (top surface) 2a, a bottom surface 2b opposite to the ceiling surface 2a, two side surfaces 2c which are located between the ceiling surface 2a and bottom surface 2b and opposite to each other, and aback surface 2cc (see FIG. 2) as another side surface opposite to the opening 2d and has the shape of a box with one surface as the opening 2d.

A handle 2j is provided in the center of the ceiling surface 2a of the main body 2 so that the FOUP 1 can be grasped.

The cover 3 is tightly attached to a brim 2e around the opening 2d of the main body 2. As shown in FIG. 2, the internal space 2k can be made a virtually sealed atmosphere by fitting the cover 3 into the brim 2e.

The internal space 2k of the main body 2 of the FOUP 1 can house a plurality of semiconductor wafers 4 in a manner that they are stacked and spaced apart; for example, it can house about 24 wafers. The number of semiconductor wafers 4 which can be housed is not limited to 24.

The FOUP 1 has two first holes and two second holes in the main body 2. In the FOUP 1 according to the first embodiment, two first holes are provided in the ceiling surface 2a and two second holes are provided in the bottom surface 2b. In the first embodiment, the two first holes in the ceiling surface 2a are intake holes 2f and the two second holes in the bottom surface 2b are exhaust holes 2h. In other words, either the first holes or the second holes are provided in the ceiling surface 2a and the other holes (the first or second holes) are provided in the bottom surface 2b.

The two first holes in the ceiling surface 2a and the two second holes in the bottom surface 2b are opposite to each other. Specifically, in the FOUP 1 according to the first embodiment, the two intake holes 2f in the ceiling surface 2a and the two exhaust holes 2h in the bottom surface 2b are located near the opening 2d (front side in the depth direction), facing each other.

Filters 2g and 2i are provided on the holes in a manner to cover the holes. Specifically, the intake holes 2f are covered by the filters 2g and the exhaust holes 2h are covered by the filters 2i.

The filters 2g and 2i are HEPA (High Efficiency Particulate Air) filters and made of grafiber or similar material. However, the filters are not limited to HEPA filters.

In the above structure of the FOUP 1, as shown in FIGS. 1 and 2, with the semiconductor wafer 4 housed in the internal space 2k of the main body 2, external air is taken into the internal space 2k from the intake holes (first holes) 2f in the ceiling surface 2a through the filters 2g and air 7 in the internal space 2k is taken out of the main body 2 from the exhaust holes 2h in the bottom surface 2b.

In other words, with semiconductor wafer 4 housed in the FOUP 1, external air is taken into the FOUP and the air 7 stagnating in the FOUP is taken out of the FOUP so that the inside of the FOUP is ventilated.

In the first embodiment, for example, a downflow 6 of N₂, etc. outflowing from above is used in a cleanroom 9 as shown in FIG. 3. In the cleanroom 9, the FOUP 1 is placed on projections 5a of a FOUP stand 5 and the air 7 of downflow 6 from above is taken into the FOUP from the intake holes 2f in the ceiling surface 2a through the filters 2g as shown in FIG. 2. On the other hand, the air 7 stagnating in the FOUP is taken out of the FOUP 1 from the exhaust holes 2h in the bottom surface 2b. The inside of the FOUP is thus ventilated. In other words, the outgas stagnating in the FOUP can be discharged from the bottom surface 2b.

The filters 2g on the intake holes 2f prevent the infiltration of foreign substances through the intake holes 2f.

The filters 2i on the exhaust holes 2h in the bottom surface 2b have the function as a valve: only when the pressure of the air 7 is given by the downflow 6, the valve is opened by the pressure of the air 7 and the internal air 7 is discharged and when the pressure of the air 7 is not given, the valve is closed to prevent the infiltration of foreign substances from the outside.

Next, the environment in which the FOUP 1 according to the first embodiment is used will be described referring to FIG. 3.

FIG. 3 shows a purge station 8 in which an area for a stocker 10 and an area for the cleanroom 9 are provided. N₂ gas from the ceiling flows into the area for the stocker 10 and the area for the cleanroom 9 as a downflow 6.

In the area for the stocker 10, the FOUP is purged of N₂ and the FOUP itself is stored. In the area for the cleanroom 9, the wafer is processed as prescribed in a processing apparatus (production apparatus) 11.

For example, as illustrated by section P and section Q of the stocker 10 shown in FIG. 3, a plurality of FOUPs 1 housing wafers are placed on a plurality of shelves 10a and the FOUPs 1 are stored there. For each FOUP 1 in the section P, N₂ gas is supplied into the FOUP through a purge port 2m in order to prevent oxidation inside the FOUP. On the other hand, the inside of each of the FOUPs 1 temporarily stored in the section Q is ventilated using the downflow 6 going into the stocker 10.

In the area for the cleanroom 9 as well, the inside of the FOUP can be ventilated using the downflow 6 going into the cleanroom 9. For example, when the required processing is finished by the processing apparatus 11 in the area for the cleanroom 9, the FOUP 1 housing the wafer is placed on a stage 11a of the processing apparatus 11 and the wafer is temporarily stored therein, the inside of the FOUP can be ventilated using the downflow 6 coming from above.

In these cases, in the stocker 10 or in the area for the cleanroom 9, the downflow 6 is taken into the internal space 2k through the intake holes 2f in the ceiling surface 2a as shown in FIG. 1 and the air 7 in the internal space 2k is taken out of the main body 2 through the exhaust holes 2h in the bottom surface 2b like the FOUP 1 shown in FIG. 2. The inside of the FOUP is thus ventilated.

The existence of the filters 2g and 2i on the intake holes 2f and exhaust holes 2h prevents the infiltration of foreign substances from the outside into the FOUP when the downflow 6 is taken into the internal space 2k.

As described above, in the FOUP 1 according to the first embodiment, the inside of the FOUP can be ventilated to discharge the outgas stagnating in the FOUP without using a special exhaust facility.

Consequently, occurrence of defects of the semiconductor substrate (semiconductor wafer 4) due to outgas can be suppressed. In short, product defects due to outgas can be suppressed.

Next, a variation of the first embodiment will be described.

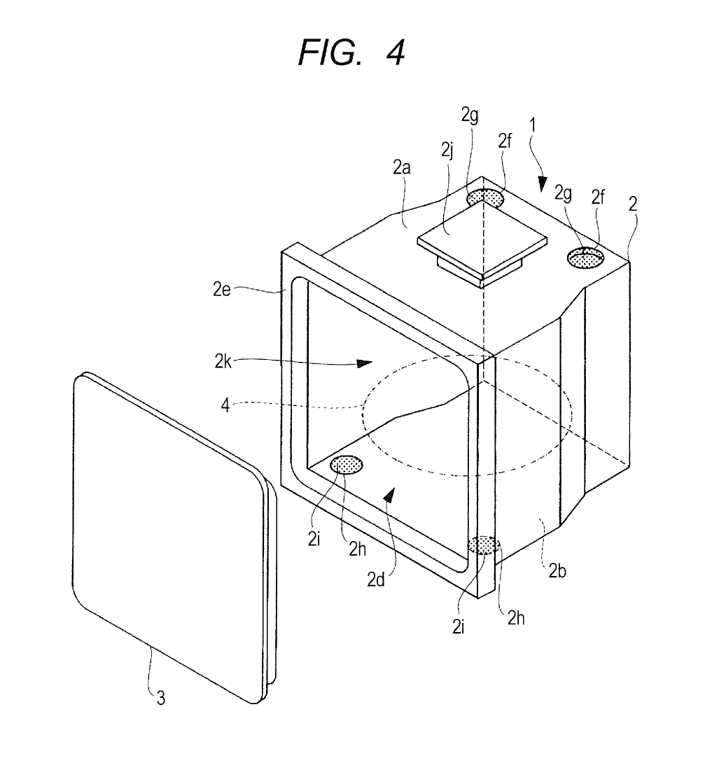

FIG. 4 is a perspective view showing the structure of the FOUP as a variation of the first embodiment.

In the FOUP 1 as a variation shown in FIG. 4, the intake holes 2f in the ceiling surface 2a are located not near the opening 2d but near the back surface 2cc (see FIG. 2) (back side in the depth direction). Specifically, the two intake holes 2f in the ceiling surface 2a are located on the back surface 2cc side of the ceiling surface 2a. On the other hand, the two exhaust holes 2h in the bottom surface 2b are located on the opening 2d side of the bottom surface 2b.

In other words, the intake holes 2f and exhaust holes 2h are located so that when the FOUP 1 is viewed sideways, the air 7 in the FOUP flows obliquely from the back surface 2cc side (back side) toward the opening 2d (front side) during ventilation.

Like the FOUP 1 shown in FIG. 1, the filters 2g and the filters 2i are provided on the intake holes 2f and exhaust holes 2h, respectively.

Consequently, in the FOUP 1 as the variation shown in FIG. 4, the inside of the FOUP can be ventilated and the outgas stagnating in the FOUP can be discharged without using a special exhaust facility, as in the FOUP 1 shown in FIG. 1.

As a result, occurrence of defects of the semiconductor substrate (product defects) due to outgas can be suppressed.

### Second Embodiment

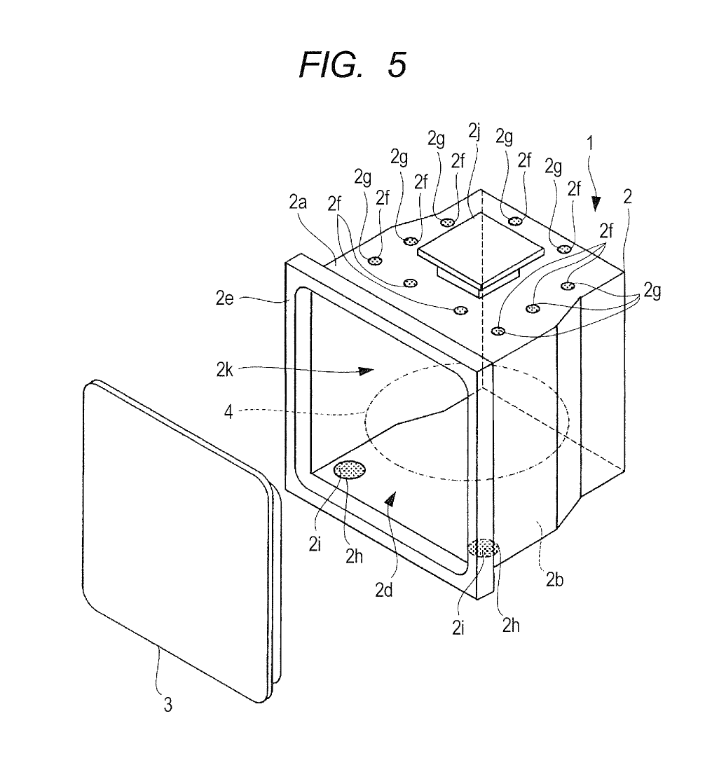

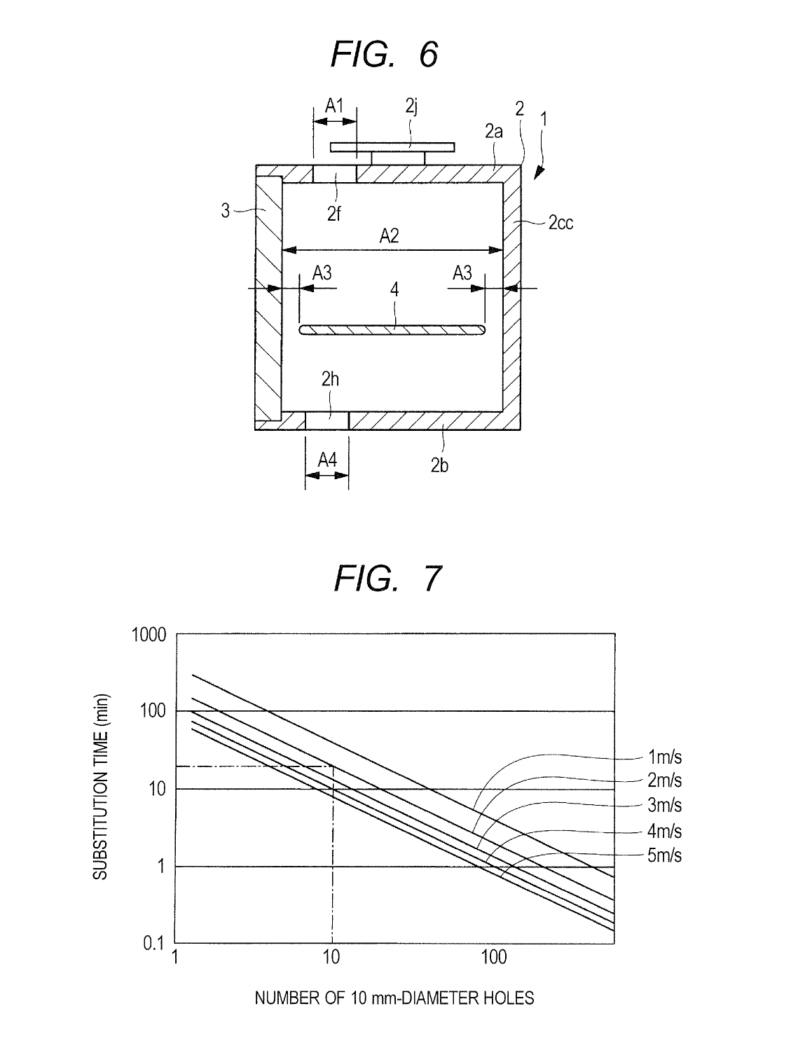

FIG. 5 is a perspective view showing an example of the structure of the FOUP according to the second embodiment; FIG. 6 is a sectional view showing the preconditions used for simulation in the FOUP according to the second embodiment; and FIG. 7 is a data graph showing the result of simulation with the FOUP according to the second embodiment.

In the second embodiment, the size and number of first holes of the FOUP 1 which ensure the achievement of the ventilation effect are calculated in consideration of the strength of the main body 2 and the position of the handle 2j.

FIG. 5 shows the structure of the FOUP 1 as calculated by the above simulation, in which ten intake holes 2f are provided in the ceiling surface 2a. Specifically, ten intake holes 2f are arranged dispersedly around the handle 2j on the ceiling surface 2a.

Next, the conditions for the above simulation shown in FIGS. 6 and 7 will be described.

On the assumption that the FOUP housing a wafer is placed in the stocker 10 shown in FIG. 3, the preconditions for the simulation are as follows: the inside dimensions of the FOUP are 300 mm×300 mm×300 mm and the diameter of an exhaust hole 2h in the bottom surface 2b of the FOUP 1 is 30 mm.

The flow rate Q of N₂ in the stocker 10 can be calculated in accordance with equation Q=CA×(2×P÷ρ)^{1/2} and Q is 0.09−0.45 m³/s(speed: 1−5 m/s). As for the flow path areas A in the FOUP, A1, A2, A3, and A4 in FIG. 6 (in the order of the flow) have the following conditions. For A1, a plurality of intake holes 2f with a diameter of 10 mm are provided in the ceiling surface 2a of the FOUP 1; for A2, the sectional area of the space in the FOUP which is not occupied by a wafer is 0.09 m²; for A3, the sectional area of the opening of the space occupied by a wafer is 0.0193 m²; and for A4, exhaust holes 2h are provided in the bottom surface 2b for discharge out of the FOUP. The coefficient of discharge C is 0.625, the pressure/atmospheric pressure P is 101325 Pa, and N₂ density ρ is ρ=1.25 kg/m³.

Under the above preconditions, assuming that the N₂ flow velocity is the same as the conveying speed of an OHT (Overhead Hoist Transport) and the FOUP stays for 10 minutes in the stocker 10, the number of intake holes 2f with a diameter of 10 mm in the ceiling surface 2a of the FOUP 1 should be about ten, as shown in FIG. 7.

FIG. 7 shows the result of the simulation to find the relation between the number of 10 mm-diameter holes and the time of N² substitution inside the FOUP in the stocker, namely how many 10 mm-diameter intake holes 2f should be provided. According to the simulation, it has been found that if ten 10 mm-diameter intake holes 2f are provided, ventilation of the inside can be finished in ten minutes.

The FOUP 1 shown in FIG. 5 is a FOUP which is designed on the basis of the simulation result and in consideration of the position of the handle 2j, the strength of the main body 2 and other factors.

As discussed above, if the flow velocities in the simulation result shown in FIG. 7 can be achieved, the inside of the FOUP can be properly ventilated even by the downflow 6.

The number of intake holes 2f is not limited to ten but it may be any other number larger than one, in consideration of the simulation result, the strength of the main body 2 and other factors.

### Third Embodiment

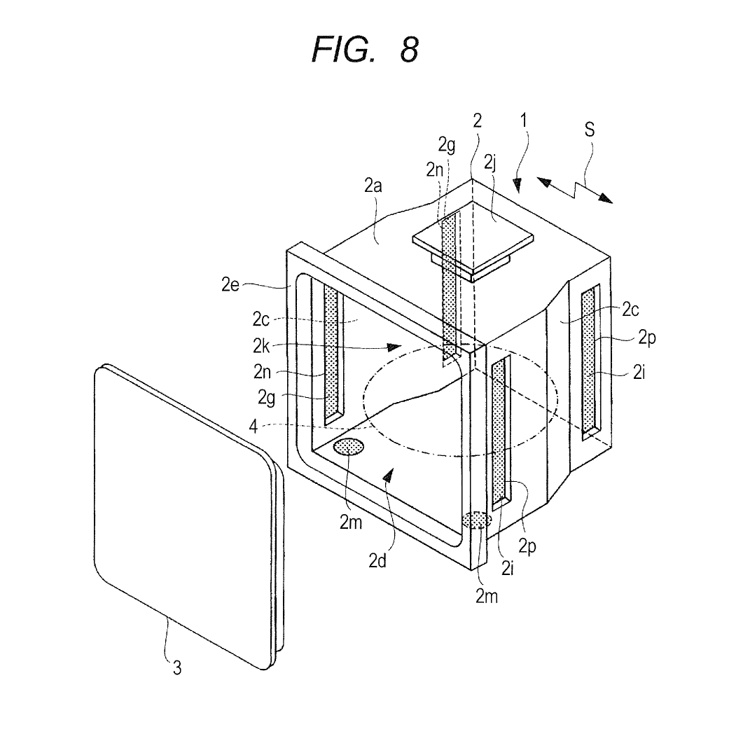

FIG. 8 is a perspective view showing an example of the structure of the FOUP according to the third embodiment.

In the FOUP 1 shown in FIG. 8, the main body 2 includes a ceiling surface 2a, a bottom surface 2b opposite to the ceiling surface 2a, two side surfaces 2c which are located between the ceiling surface 2a and bottom surface 2b and opposite to each other. Either the first holes or the second holes are provided in one of the side surfaces 2c and the other holes (the first or second holes) are provided in the other side surface 2c. The first holes and the second holes are long holes (first holes) 2n and long holes (second holes) 2p which extend along the height direction (wafer stacking direction) from the bottom surface 2b of the main body 2 to the ceiling surface 2a, respectively.

In the FOUP 1 shown in FIG. 8, two long holes 2n and 2p are formed in the opposite side surfaces 2c. Specifically, the long holes 2n are formed near the opening 2d and near the back surface 2cc (see FIG. 2) in one side surface 2c and the long holes 2p are formed near the opening 2d and near the back surface 2cc in the other side surface 2c. In other words, in the two opposite side surfaces 2c, the long holes 2n and long holes 2p are provided near the opening 2d and near the back surface 2cc so that the long hole 2n and long hole 2p near the opening 2d face each other and the long hole 2n and long hole 2p near the back surface 2cc face each other.

Filters 2g and 2i are provided on the long holes 2n and long holes 2p. Specifically, the filters 2g are provided on the long holes 2n and the filters 2i are provided on the long holes 2p.

The FOUP 1 shown in FIG. 8 which houses a wafer 4 is moved by the OHT (unmanned traveling vehicle) in the cleanroom and for example, the air flow generated by movement of the OHT is taken into the internal space 2k through the long holes 2n and the air 7 in the internal space 2k is taken out of the main body 2 through the other opposite long holes 2p. In short, the air flow generated by movement of the OHT is used to ventilate the inside of the FOUP 1.

Consequently, the inside of the FOUP can be ventilated so that occurrence of semiconductor substrate defects (product defects) due to outgas can be suppressed.

For the FOUP 1 shown in FIG. 8, the direction in which the OHT moves is, for example, direction S along the direction which couples the long holes 2n and the long holes 2p opposite to the long holes 2n.

The formation of the long holes 2n and 2p in the opposite side surfaces 2c of the FOUP 1 enables automatic internal ventilation by the movement of the OHT, etc. to convey the FOUP 1. This means that internal ventilation can be automatically performed during conveyance of the FOUP regardless of whether or not there is a downflow 6 and the outgas stagnating inside the FOUP can be discharged.

The filters 2g and 2i on the long holes 2n and 2p prevent the infiltration of foreign substances together with external air during ventilation.

In the FOUP 1 shown in FIG. 8, the long holes (first holes) 2n and long holes (second holes) 2p which extend along the height direction (wafer stacking direction) of the main body 2 are formed in the side surfaces 2c. Consequently, when the inside of the FOUP 1 is ventilated by taking the air flow generated by movement of the FOUP 1 inwards, the air flow can be made to pass through gaps between stacked wafers, so even if a plurality of wafers are stacked in the FOUP 1, internal ventilation can be performed properly and the internal outgas can be discharged reliably.

The conveying means is not limited to the above vehicle (OHT). For example, even when a conveying mechanism such as a belt conveyor is used, the same effect can be achieved.

### Fourth Embodiment

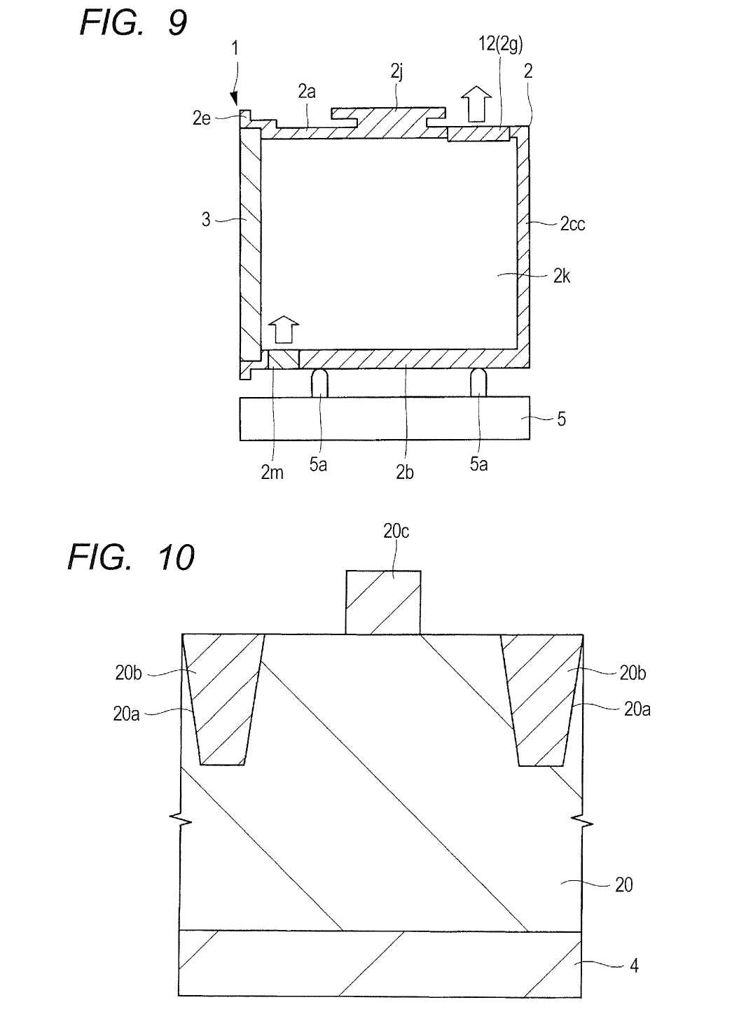

FIG. 9 is a sectional view showing an example of the structure of the FOUP according to the fourth embodiment.

In the FOUP 1 shown in FIG. 9, either the first hole or the second hole is an exhaust or intake fan 12 provided in the ceiling surface 2a of the main body 2 and the other hole (first hole or second hole) is a purge port 2m provided in the bottom surface 2b opposite to the ceiling surface 2a.

For example, an exhaust fan 12 is provided in the ceiling surface 2a and external air is taken in through the purge port 2m provided in the bottom surface 2b and the outgas inside the FOUP is discharged to the outside by the fan 12 in the ceiling surface 2a. The inside of the FOUP is thus ventilated. The fan 12 has a power source outside the FOUP 1 and for example, when the FOUP 1 is placed on the FOUP stand 5, the power is supplied to start the fan 12.

However, the fan 12 is not limited to an electric fan but it may be rotated by air.

In other words, the FOUP 1 according to the fourth embodiment is provided with the fan 12 so that ventilation can be performed without the need for a downflow 6 or an air flow generated by movement.

Since the fan 12 does not always rotate, a filter 2g is also provided on the fan 12 to prevent the infiltration of foreign substances from the outside.

Alternatively, the fan 12 may be an intake fan and in that case, external air is taken in through the fan 12 and internal outgas is discharged through an exhaust hole 2h in the bottom surface 2b to ventilate the inside of the FOUP.

In the FOUP 1 according to the fourth embodiment as well, the inside of the FOUP can be ventilated by the use of the exhaust or intake fan 12 so that occurrence of semiconductor substrate defects (product defects) due to outgas can be suppressed.

### Fifth Embodiment

FIGS. 10 to 20 are fragmentary sectional views of an example of the essential part of the semiconductor substrate manufactured by the semiconductor device manufacturing method according to the fifth embodiment.

The fifth embodiment concerns a case that while the FOUP is temporarily stored between steps of processing the semiconductor substrate in the semiconductor device manufacturing process, the inside of the FOUP housing a wafer is ventilated. The fifth embodiment is explained below by giving an example of the steps of forming the essential part of a transistor such as a MOSFET (Metal Oxide Semiconductor Field Effect Transistor) in a semiconductor substrate.

First, as shown in FIG. 10, a trench 20a to form an element separation region in a semiconductor wafer (semiconductor substrate) 4 is made by etching and an insulating material is buried in the trench 20a to form an STI (Shallow Trench Isolation) 20b and obtain an element separation region. Then, P-type impurities are implanted into the semiconductor wafer 4 to form a P well 20. After the formation of the P well 20, a gate insulating film (not shown) is formed over the front surface of the semiconductor wafer 4 and a MOSFET gate electrode 20c is formed over the gate insulating film. The gate electrode 20c includes a conductive film such as a poly-Si film. Although not shown, a low-concentration diffusion region may be formed over the semiconductor wafer 4 on the lateral side of the gate electrode 20c, as an impurity region with a lower impurity concentration than a diffusion layer 20f which will be described later.

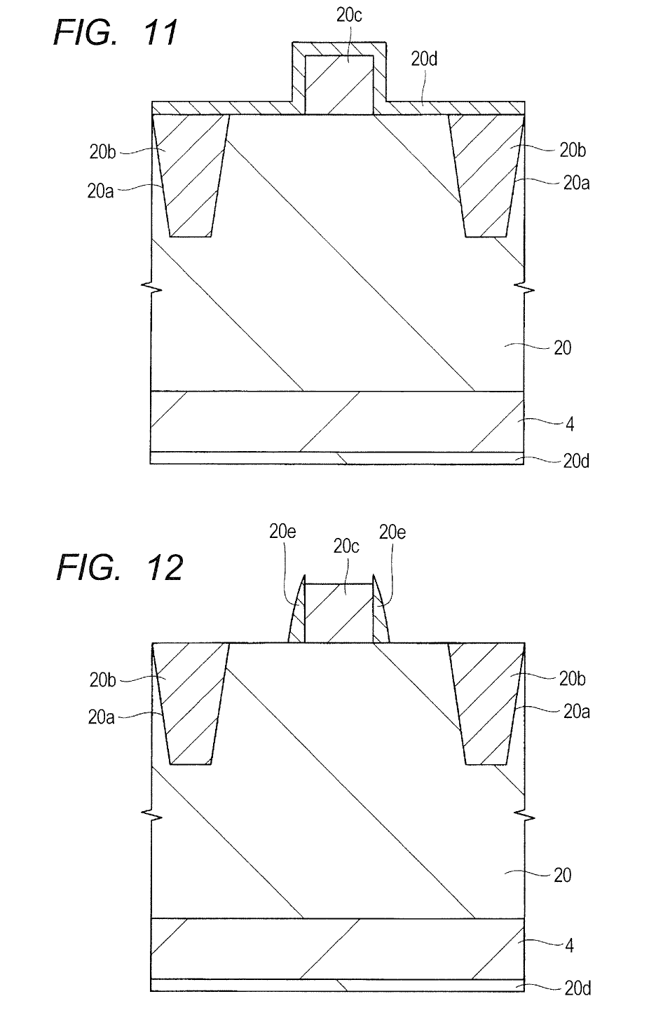

After the formation of the gate electrode 20c, a SiN film 20d is formed over the surface of the P well 20 and over the gate electrode 20c as shown in FIG. 11. At this time, a SiN film 20d may be formed over the back surface of the semiconductor wafer 4 as well. However, only an etching stopper film (SiN film) which will be described later may be formed over the back surface.

After the formation of the SiN film, a sidewall spacer 20e is formed by anisotropically etching the SiN film 20d as shown in FIG. 12. Specifically, the sidewall spacer 20e of SiN film (first insulating film) 20d is formed on the sidewall of the gate electrode 20c by anisotropically etching the SiN film 20d over the surface of the P well 20 and over the surface of the gate electrode 20c. The first insulating film contains Si (silicon) and N (nitrogen).

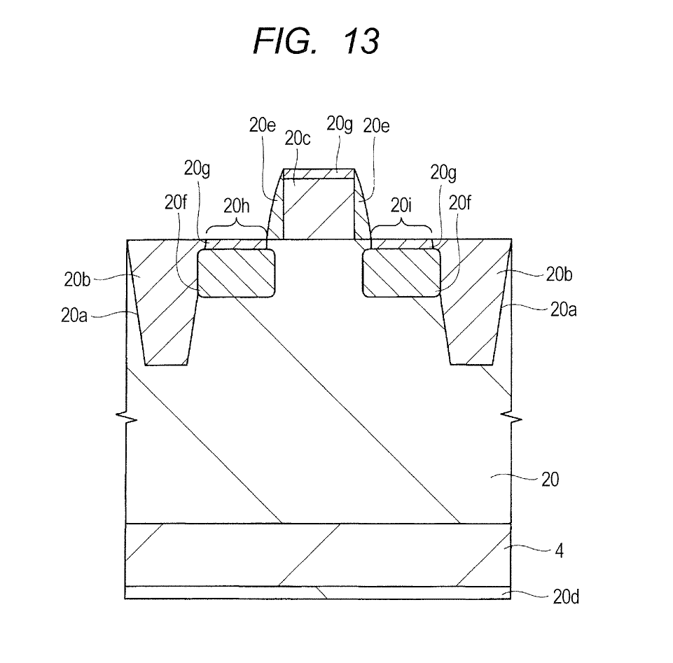

Next, as shown in FIG. 13, an N-type diffusion layer 20f is formed on the front surface side of the semiconductor wafer 4 and a silicide 20g is formed over the N-type diffusion layer 20f and the gate electrode 20c to form a source region 20h and a drain region 20i.

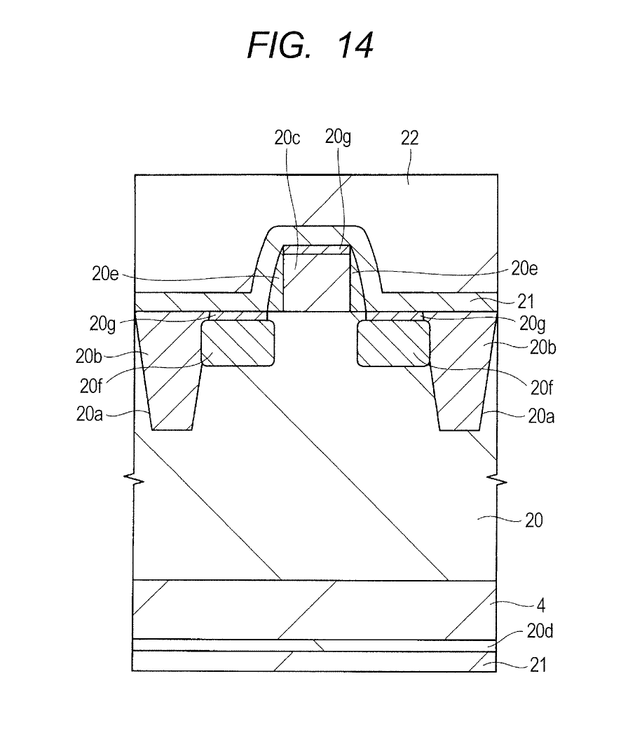

After the formation of the source region 20h and drain region 20i, a SiN film (second insulating film) 21 as an etching stopper film is formed as shown in FIG. 14. Specifically, the SiN film 21 as an etching stopper film is formed over the gate electrode 20c, over the sidewall spacer 20e, and over the source region 20h and drain region 20i shown in FIG. 13. At this time, a SiN film 21 may be formed as an etching stopper film over the back surface of the semiconductor wafer 4. However, only the SiN film 20d as the sidewall spacer 20e may lie over the back surface. The second insulating film also contains Si (silicon) and N (nitrogen). After the formation of the etching stopper film, a SiO film 22 as an interlayer film for a contact plug is formed over the SiN film 21 as the etching stopper film.

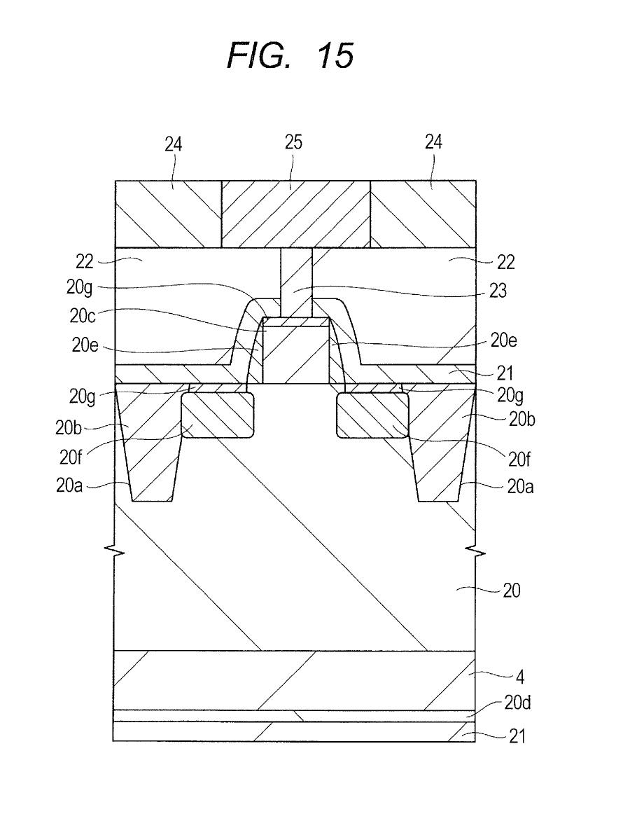

After the formation of the SiO film 22, a contact plug 23 which is buried in the SiN film 21 and SiO film 22 is formed as shown in FIG. 15. The contact plug 23 is formed in a manner to contact the silicide 20g over the gate electrode 20c. Although not shown, the contact plug 23 is formed in a manner to contact the silicide 20g over the N-type diffusion layer 20f as well. After the formation of the contact plug 23, an interlayer insulating film (first interlayer insulating film) 24 for a first wiring is formed as an interlayer film over the SiO film 22 and the contact plug 23. After the formation of the interlayer insulating film 24, Cu wiring 25 as a first wiring is formed in a manner to be buried in the interlayer insulating film 24. The Cu wiring 25 is formed, for example, by forming a trench in the interlayer insulating film 24 by a damascene technique and burying Cu (copper-based material) in the trench.

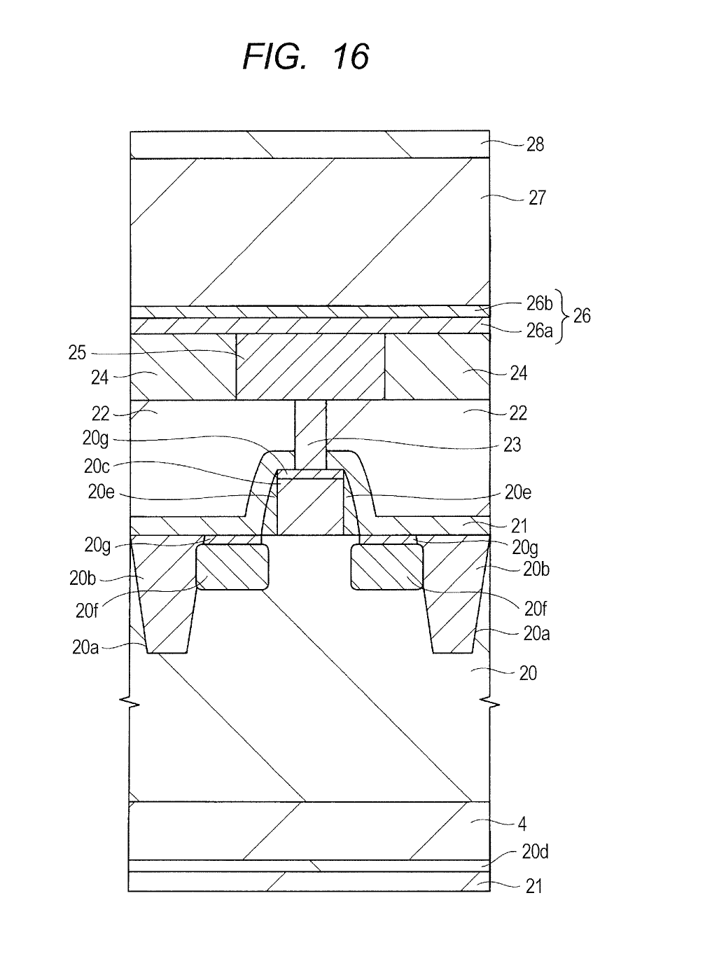

After the formation of the Cu wiring 25, a barrier insulating film 26 is formed over the interlayer insulating film 24 and Cu wiring 25 as shown in FIG. 16. The barrier insulating film 26 includes a SiCN film 26a and a SiCo film 26b; first, the SiCN film 26a is formed over the interlayer insulating film 24 and Cu wiring 25, then the SiCO film 26b is formed over the SiCN film 26a. The barrier insulating film 26 is thus formed. As described above, the barrier insulating film 26 contains nitrogen or oxygen as well as silicon and carbon. After the formation of the barrier insulating film 26, an interlayer insulating film (second interlayer insulating film) 27 for a second wiring is formed as an interlayer film over the barrier insulating film 26. The interlayer insulating film 27 is, for example, a SiOC film but it may be made of a material with a low dielectric constant. After the formation of the interlayer insulating film 27, a SiO film 28 is formed as a gap film over the interlayer insulating film 27.

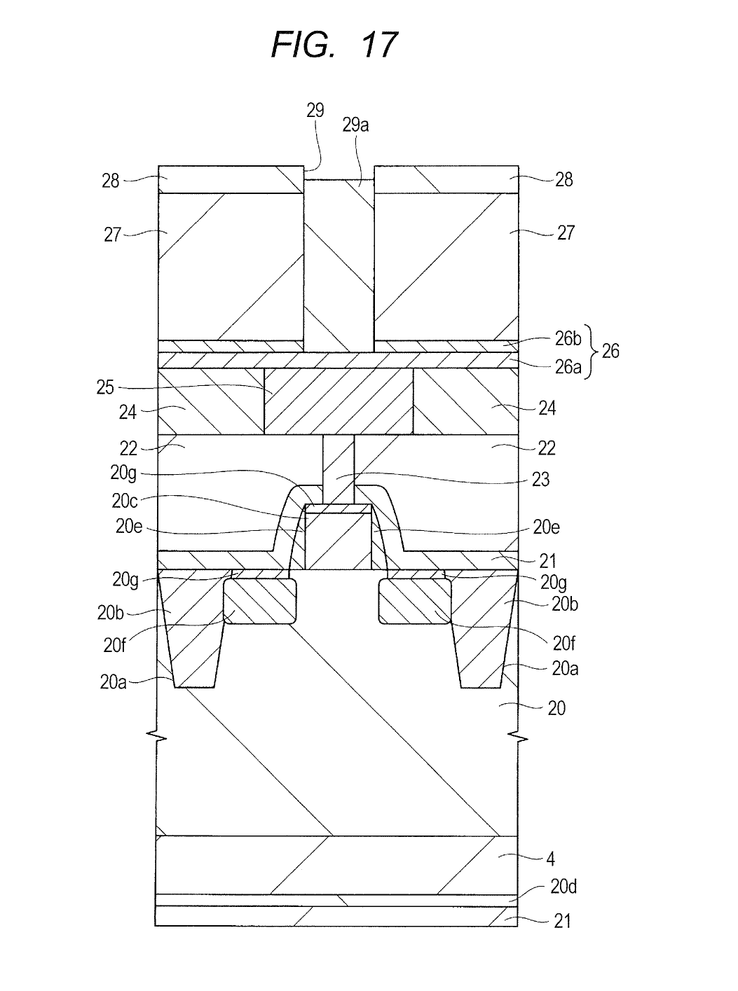

After the formation of the SiO film 28, a via 29 as a contact hole is formed in the interlayer insulating film 27 as shown in FIG. 17. More specifically, the via 29 as a hole is formed in the SiCO film 26b among the SiO film 28, interlayer insulating film 27 and barrier insulating film 26. After the formation of the via 29, a via-fill material 29a as an organic film is formed (buried) in the via 29. The via-fill material 29a is an organic material similar to resist, etc.

After the formation of the via-fill material 29a, the semiconductor wafer 4 is temporarily stored in the FOUP. More specifically, the semiconductor wafer 4 already subjected to the steps up to the formation of the via-fill material 29a is housed in the FOUP for temporary storage. At the step of storing the semiconductor wafer 4 temporarily, at least one of the SiN film (first insulating film) 20d and the SiN film (second insulating film) 21 has been formed on the back surface of the semiconductor wafer 4. In the semiconductor wafer 4 according to the fifth embodiment, both the SiN film 20d and the SiN film 21 have been formed on the back surface.

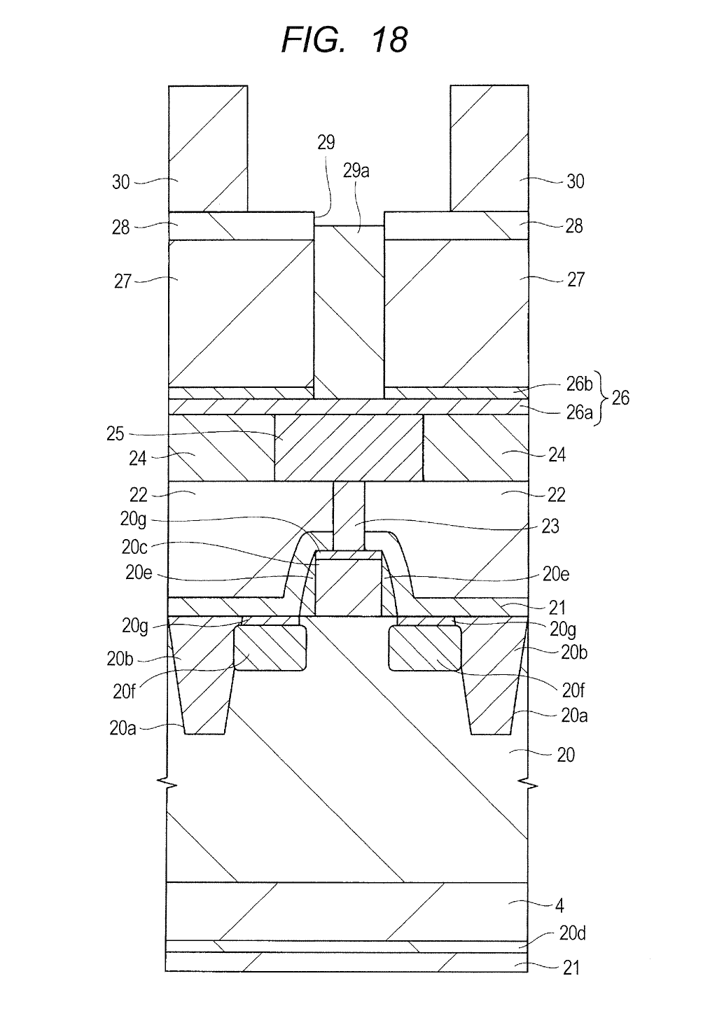

The semiconductor wafer 4 thus processed is housed, for example, in the FOUP 1 shown in FIG. 1 for temporary storage. It is known that at this time a lot of amine is generated from the SiN film 20d and the SiN film 21 on the back surface of the semiconductor wafer 4, the SiCN film 26a of the barrier insulating film 26, and the via-fill material 29a. If a lot of amine is generated, there may arise a problem that the pattern of a resist film 30 (see FIG. 18) cannot be properly made at the next step.

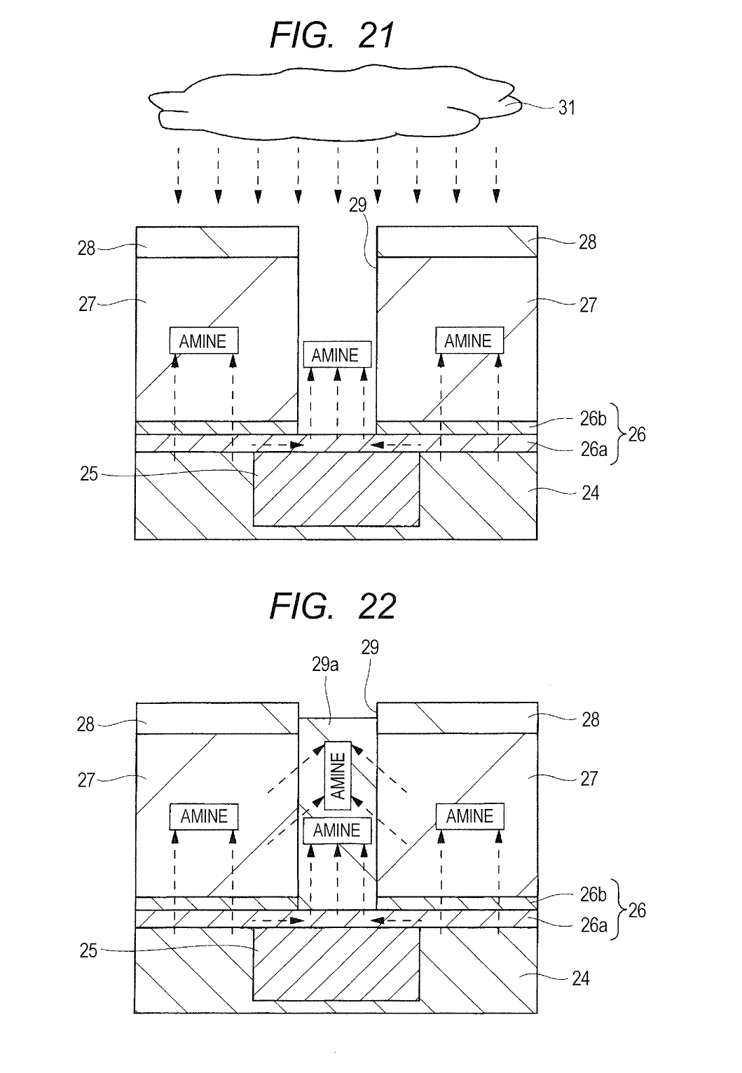

Next, the mechanism which causes the above problem will be explained referring to FIGS. 21 to 23. FIGS. 21 to 23 are fragmentary sectional views of the structure of the essential part of the semiconductor substrate, showing how the problem occurs in the embodiments.

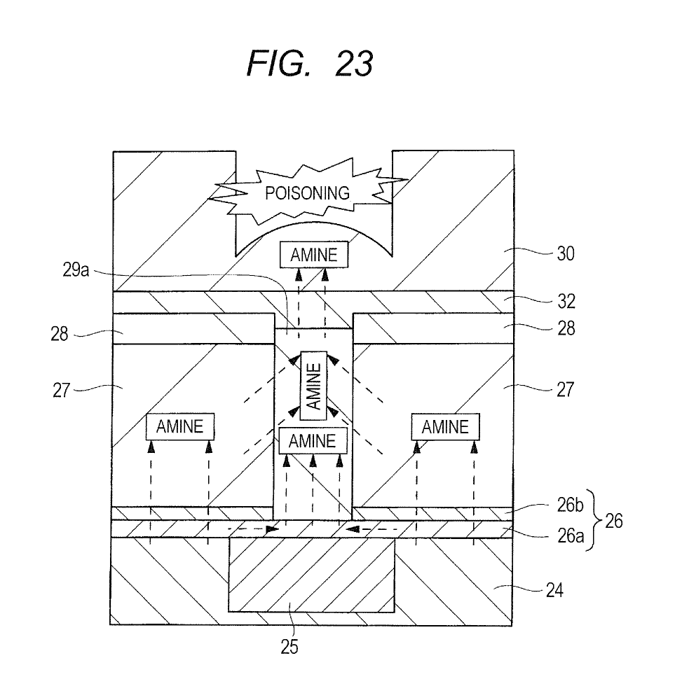

The reason that the resist film 30 is not made properly at the next step as mentioned above is occurrence of a development failure called poisoning as shown in FIG. 23. The mechanism shown in FIGS. 21 to 24 is generally known as the mechanism which causes poisoning. As shown in FIG. 21, amine is generated from the SiCN film, etc. as an amine source and its diffusion is accelerated by absorption of moisture 31. Furthermore, as shown in FIG. 22, it diffuses through the via-fill material 29a as the organic material buried in the via 29 and the amine concentration near the via pattern increases. Consequently, as shown in FIG. 23, the amine which has passed through an anti-reflection layer 32 arrives at the resist film 30 and causes a development failure of the resist film 30 there. As a result, trench pattern thinning or formation failure occurs during the formation of the resist film 30 at the next step. The resist film 30 here is, for example, ArF resist.

Furthermore, if, during the step of forming the via (contact hole) 29, an ammonia plasma process is performed in order to reduce the oxide on the Cu wiring surface after the formation of the via 29 and before burying the via-fill material 29a in the via 29, the ammonia plasma-processed layer on the surface of the interlayer insulating film 24 as a SiOC film becomes an amine source and generates a lot of amine.

As far as the work-in-process is concerned, a SiN film is formed on the wafer back surface before the formation of the via (contact hole) 29, in order to eliminate the possibility that metal ion contamination occurs in the silicon substrate (semiconductor wafer 4) from the lower stage of the production apparatus for the wiring process, the conveyor robot arm or the like through the wafer back surface. The SiN film on the wafer back surface is, for example, an LP—SiN film as an etching stopper film. In some cases, it may be formed as a sidewall spacer film. It has been found from an investigation by the present inventors that NH₄+ ions emitted from the SiN film on the wafer back surface has an influence on the increase in the amount of amine on the wafer front surface. The problem is that the amine concentration in the FOUP rapidly increases while the wafer is stored in the FOUP.

Therefore, in the semiconductor device manufacturing method according to the fifth embodiment, while the semiconductor wafer 4 already subjected to the steps up to the formation of the via-fill material 29a is housed in the FOUP and temporarily stored, the inside of the FOUP is ventilated in the cleanroom 9 shown in FIG. 3 using a downflow 6. Specifically, in the FOUP 1 shown in FIG. 1, external air is taken into the internal space 2k from the intake holes 2f in the ceiling surface 2a of the main body 2 through the filters 2g and the air 7 in the internal space 2k as shown in FIG. 2 is taken out of the main body 2 from the exhaust holes 2h in the bottom surface 2b. In short, the inside of the FOUP is ventilated.

Consequently, the amine outgas stagnating in the FOUP is taken out of the main body 2. As a result, the amine concentration in the FOUP decreases, so occurrence of poisoning (development failure) as mentioned above at the next step is suppressed and a correct pattern resist film 30 as shown in FIG. 18 which will be described later is formed.

The formation of a correct pattern resist film 30 suppresses the occurrence of semiconductor substrate defects due to outgas, resulting in improvement in the product yield rate. In addition, the desired shape of the wiring trench is maintained, leading to improvement in the reliability of the semiconductor device.

After the ventilation of the FOUP 1 (temporary storage of the wafer) is finished, the wafer is conveyed to the prescribed production apparatus through the FOUP 1 and a resist film (resist pattern) 30 to make a trench is formed over the interlayer insulating film (second interlayer insulating film) 27 as shown in FIG. 18.

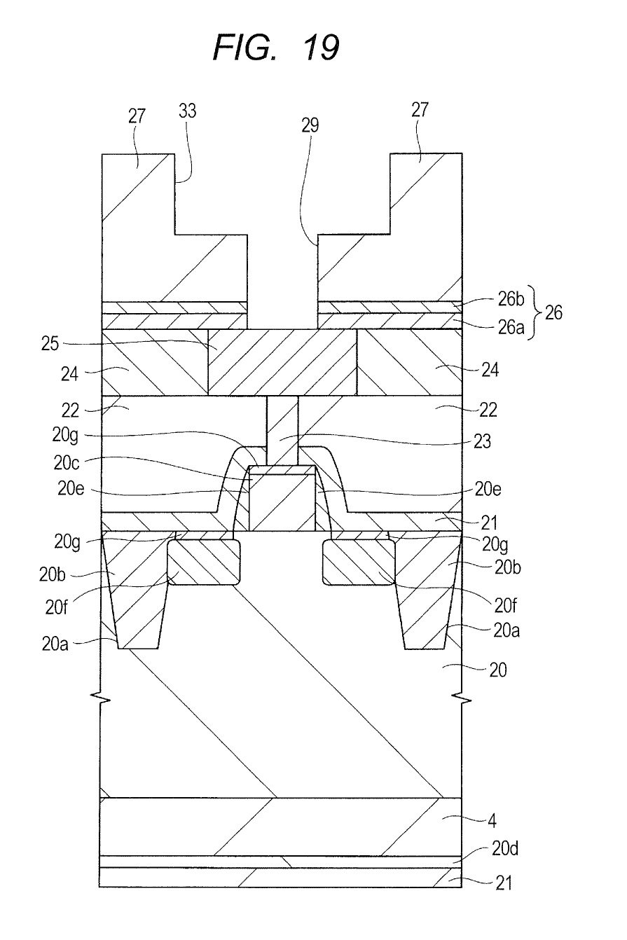

After the formation of the resist film 30, a trench 33 to be coupled with the via (contact hole) 29 is made in the interlayer insulating film 27 by etching, using the resist film 30 as a mask as shown in FIG. 19. After the formation of the trench 33, the resist film 30 is removed by asking. At this time, the via-fill material (organic film) 29a in the via 29 is also removed. After the removal of the resist film 30 and the via-fill material 29a, the SiCN film 26a as the barrier insulating film 26 on the bottom of the via (contact hole) 29 is removed. The surface of the Cu wiring (first wiring) 25 is thus exposed.

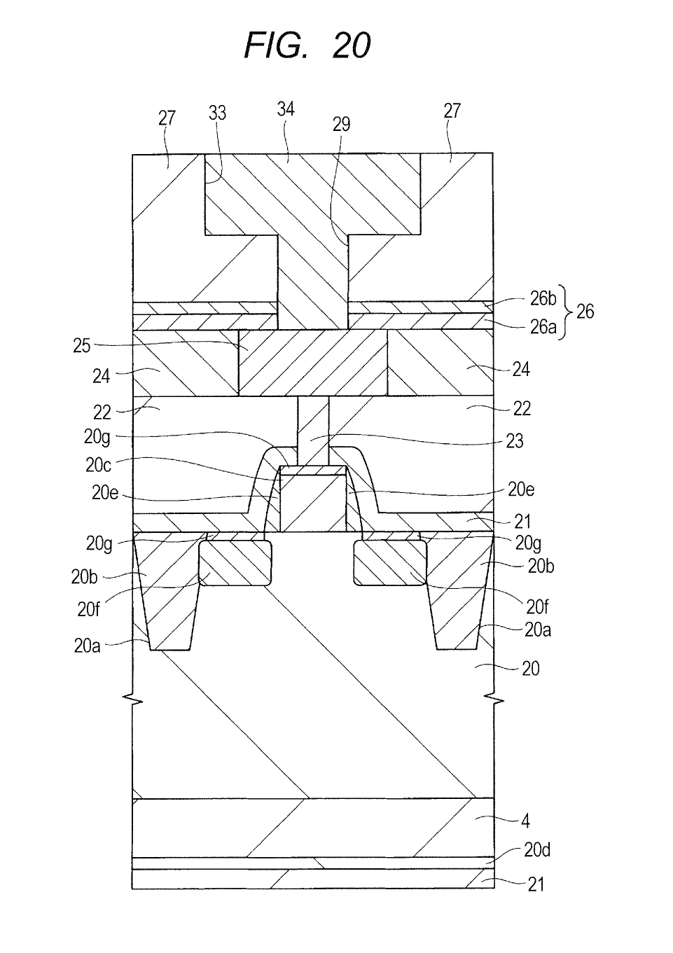

After the removal of the SiCN film 26a, a Cu wiring 34 as a conductive film is formed in a manner to be buried in the trench 33 and the via (contact hole) 29 as shown in FIG. 20. The Cu wiring 34 is made of a copper-based material and formed by burying copper in the trench 33 and via 29 by a plating technique. The copper outside the trench is removed by CMP (Chemical Mechanical Polishing). The overlying Cu wiring (conductive film) 34 coupled with the underlying Cu wiring (first wiring) 25 is thus formed.

The invention made by the present inventors has been so far explained concretely in reference to the preferred embodiments thereof. However, the invention is not limited thereto and it is obvious that these details may be modified in various ways without departing from the spirit and scope thereof.

The fifth embodiment has been described above on the assumption that a SiN film is formed on the wafer back surface but even when a SiN film is not formed on the wafer back surface, the amine concentration in the FOUP can be decreased by ventilating the inside of the FOUP using the FOUP 1 according to any one of the first to fourth embodiments.

The fifth embodiment has been described above on the assumption that the wafer is stored in the FOUP when a wiring trench is made, but not limited thereto. For example, even when the wafer is stored after the formation of the sidewall spacer 20e and etching stopper film 21, the amine concentration can be kept low by using the FOUP according to one of the above embodiments for storage.

In the FOUPs 1 according to the first to fourth embodiments, at least one hole should be formed in each of the two opposite surfaces of the main body 2 (for example, the ceiling surface 2a and bottom surface 2b or the two opposite side surfaces 2c) and the holes should be each provided with a filter. The number of holes with a filter in one surface is not limited.

Some details of the embodiments described above are given below:

### Note 1

A semiconductor device manufacturing method which includes the steps of:
(a) forming a gate insulating film over a front surface of a semiconductor substrate;
(b) forming a gate electrode over the gate insulating film;
(c) forming a sidewall spacer comprised of a first insulating film over the front surface of the semiconductor substrate and on a sidewall of the gate electrode;
(d) forming a source region and a drain region on a front surface side of the semiconductor substrate;
(e) after the steps (a) to (d), forming an etching stopper film comprised of a second insulating film over the gate electrode, over the sidewall spacer, over the source region, and over the drain region;
(f) forming a first interlayer insulating film over the etching stopper film;
(g) forming a first wiring in a manner to be buried in the first interlayer insulating film;
(h) forming a barrier insulating film over the first interlayer insulating film and over the first wiring;
(i) forming a second interlayer insulating film over the barrier insulating film;
(j) forming a contact hole in the second interlayer insulating film;
(k) forming an organic film in the contact hole;
(l) after the step (k), storing the semiconductor substrate in a FOUP temporarily;
(m) after the step (l), forming a resist pattern over the second interlayer insulating film;
(n) forming a trench to be coupled with the contact hole in the second interlayer insulating film using the resist pattern as a mask;
(o) after the step (n), removing the resist pattern and the organic film;
(p) after the step (o), exposing the surface of the first wiring by removing the barrier insulating film on a bottom of the contact hole;
(q) after the step (p), forming a conductive film to fill the trench and the contact hole, in which
the barrier insulating film contains silicon, carbon, and nitrogen;
the FOUP includes a main body having an opening for taking in or out the semiconductor substrate and including an internal space, a cover detachably attached to the main body in close contact with the main body in a manner to cover the opening, a first hole and a second hole which are formed in the main body, and a filter provided on each of the first hole and the second hole;
at the step (l), with the semiconductor substrate housed in the internal space of the FOUP, external air is taken into the internal space from one of the first hole and the second hole through the filter and air in the internal space is taken out of the main body from the other of the first hole and the second hole; and
at the step (l), the FOUP is stored in a cleanroom.

What is claimed is:

1. A semiconductor device manufacturing method comprising the steps of:
(a) forming a gate insulating film over a front surface of a semiconductor substrate;
(b) forming a gate electrode over the gate insulating film;
(c) forming a sidewall spacer comprised of a first insulating film over the front surface of the semiconductor substrate and on a sidewall of the gate electrode;
(d) forming a source region and a drain region on a front surface side of the semiconductor substrate;
(e) after the steps (a) to (d), forming an etching stopper film comprised of a second insulating film over the gate electrode, over the sidewall spacer, over the source region, and over the drain region; and
(f) after the step (e), storing the semiconductor substrate in a FOUP temporarily,
wherein the first insulating film and the second insulating film contain silicon and nitrogen,
wherein at the step (f), at least one of the first insulating film and the second insulating film is formed over a back surface of the semiconductor substrate,
wherein the FOUP includes a main body having an opening for taking in or out the semiconductor substrate and including an internal space, a cover detachably attached to the main body in close contact with the main body in a manner to cover the opening, a first hole and a second hole which are formed in the main body, and a filter provided on each of the first hole and the second hole,
wherein at the step (f), with the semiconductor substrate housed in the internal space of the FOUP, external air is taken into the internal space from one of the first hole and the second hole through the filter and air in the internal space is taken out of the main body from the other of the first hole and the second hole, and
wherein at the step (f), the FOUP is stored in a cleanroom.

2. The semiconductor device manufacturing method according to claim 1,
wherein the main body of the FOUP includes a ceiling surface and a bottom surface opposite to the ceiling surface, and
wherein one of the first hole and the second hole is provided in the ceiling surface and the other of the first hole and the second hole is provided in the bottom surface.

3. The semiconductor device manufacturing method according to claim 2,
wherein the first hole and the second hole are provided in plurality,
wherein in the cleanroom, a downflow is taken into the internal space through any one of the first hole or the second hole provided in the ceiling surface, and the air in the internal space is taken out of the main body through the other hole of the first hole or the second hole provided in the bottom surface,.

4. The semiconductor device manufacturing method according to claim 1,
wherein the main body of the FOUP includes a ceiling surface, a bottom surface opposite to the ceiling surface, and two side surfaces located between the ceiling surface and the bottom surface and opposite to each other,
wherein one of the first hole and the second hole is provided in one of the side surfaces and the other of the first hole and the second hole is provided in the other side surface, and
wherein the first hole and the second hole are long holes which extend along a height direction from the bottom surface of the main body to the ceiling surface.

5. A semiconductor device manufacturing method comprising the steps of:
(a) forming a gate insulating film over a front surface of a semiconductor substrate;
(b) forming a gate electrode over the gate insulating film;
(c) forming a sidewall spacer comprised of a first insulating film over the front surface of the semiconductor substrate and on a sidewall of the gate electrode;
(d) forming a source region and a drain region on a front surface side of the semiconductor substrate;
(e) after the steps (a) to (d), forming an etching stopper film comprised of a second insulating film over the gate electrode, over the sidewall spacer, over the source region, and over the drain region;
(f) forming a first interlayer insulating film over the etching stopper film;
(g) forming a first wiring in a manner to be buried in the first interlayer insulating film;
(h) forming a barrier insulating film over the first interlayer insulating film and over the first wiring;
(i) forming a second interlayer insulating film over the barrier insulating film;
(j) forming a contact hole in the second interlayer insulating film;
(k) forming an organic film in the contact hole;
(l) after the step (k), storing the semiconductor substrate in a FOUP temporarily;
(m) after the step (l), forming a resist pattern over the second interlayer insulating film;
(n) forming a trench to be coupled with the contact hole in the second interlayer insulating film using the resist pattern as a mask;
(o) after the step (n), removing the resist pattern and the organic film;
(p) after the step (o), exposing a surface of the first wiring by removing the barrier insulating film on a bottom of the contact hole;
(q) after the step (p), forming a conductive film to fill the trench and the contact hole,
wherein the first insulating film and the second insulating film contain silicon and nitrogen,
wherein at the step (l), at least one of the first insulating film and the second insulating film is formed over a back surface of the semiconductor substrate,
wherein the FOUP includes a main body having an opening for taking in or out the semiconductor substrate and including an internal space, a cover detachably attached to the main body in close contact with the main body in a manner to cover the opening, a first hole and a second hole which are formed in the main body, and a filter provided on each of the first hole and the second hole,
wherein at the step (l), with the semiconductor substrate housed in the internal space of the FOUP, external air is taken into the internal space from one of the first hole and the second hole through the filter and air in the internal space is taken out of the main body from the other of the first hole and the second hole, and
wherein at the step (l), the FOUP is stored in a cleanroom.

6. The semiconductor device manufacturing method according to claim 5, wherein the barrier insulating film contains silicon, carbon, and nitrogen.

7. The semiconductor device manufacturing method according to claim 5, wherein the first wiring and the conductive film are made of a copper-based material.

8. The semiconductor device manufacturing method according to claim 5, wherein the second interlayer insulating film is made of a material with a low dielectric constant.

9. The semiconductor device manufacturing method according to claim 5, further comprising the step of performing an ammonia plasma process between the steps (j) and (k).

10. A FOUP comprising:
a main body having an opening for taking in or out a semiconductor substrate and including an internal space;
a cover detachably attached to the main body in close contact with the main body in a manner to cover the opening;
a first hole and a second hole which are formed in the main body; and
a filter provided on each of the first hole and the second hole,
wherein, with the semiconductor substrate housed in the internal space of the main body, external air can be taken into the internal space from one of the first hole and the second hole through the filter and air in the internal space can be taken out of the main body from the other of the first hole and the second hole.

11. The FOUP according to claim 10,
wherein the main body includes a ceiling surface and a bottom surface opposite to the ceiling surface, and
wherein one of the first hole and the second hole is provided in the ceiling surface and the other of the first hole and the second hole is provided in the bottom surface.

12. The FOUP according to claim 11,
wherein in a cleanroom, a downflow can be taken into the internal space through one of the first hole or the second hole provided in the ceiling surface, and the air in the internal space can be taken out of the main body through the other of the first hole or the second hole provided in the bottom surface.

13. The FOUP according to claim 10,
wherein the main body includes a ceiling surface, a bottom surface opposite to the ceiling surface, and two side surfaces located between the ceiling surface and the bottom surface and opposite to each other,
wherein one of the first hole and the second hole is provided in one of the side surfaces and the other of the first hole and the second hole is provided in the other side surface, and
wherein the first hole and the second hole are long holes which extend along a height direction from the bottom surface of the main body to the ceiling surface.

14. The FOUP according to claim 13, wherein in a cleanroom, the FOUP housing the semiconductor substrate is moved and an air flow generated by the movement can be taken into the internal space through one of the first hole and the second hole and the air in the internal space can be taken out of the main body through the other of the first hole and the second hole.

15. The FOUP according to claim 10,
wherein the main body includes a ceiling surface and a bottom surface opposite to the ceiling surface, and
wherein one of the first hole and the second hole is a fan provided in the ceiling surface and the other of the first hole and the second hole is a purge port provided in the bottom surface.
